(19) United States
(12) Patent Application Publication
(10) Pub. No.: US 2026/0033132 A1
(43) Pub. Date: Jan. 29, 2026

(54) DISPLAY PANEL, DISPLAY DEVICE, AND PREPARATION METHOD FOR DISPLAY PANEL

(71) Applicant: Yungu (Gu’an) Technology Co., Ltd., Langfang (CN)

(72) Inventors: Junwei LIU, Langfang (CN); Junhui LOU, Langfang (CN); Rubo XING, Langfang (CN); Wangfeng XI, Langfang (CN); Huanhuan ZHANG, Langfang (CN); Guofei KANG, Langfang (CN); Yonglei XU, Langfang (CN); Min ZHANG, Langfang (CN)

(73) Assignee: Yungu (Gu’an) Technology Co., Ltd., Langfang (CN)

(21) Appl. No.: 19/248,362

(22) Filed: Jun. 24, 2025

(30) Foreign Application Priority Data
Jul. 25, 2024 (CN) 202411005511.2

(51) Int. Cl. H10K 50/18; H10H 29/01; H10H 29/37; H10K 50/17; H10K 59/12; H10K 59/122; H10K 102/00

(52) U.S. Cl. CPC H10K 50/18; H10H 29/012; H10H 29/37; H10K 50/17; H10K 59/1201; H10K 59/122; H10K 2102/351

(57) ABSTRACT

The present application discloses a display panel, a display device, and a preparation method for a display panel. The display panel includes a substrate, a pixel define layer, and a light-emitting device layer. The pixel define layer includes a pixel defining portion and a plurality of pixel openings. The light-emitting device layer includes a plurality of first carrier structures, a plurality of light-emitting structures, and a second carrier layer. The light-emitting structures are located on one side of corresponding first carrier structures, the side facing away from the substrate. The second carrier layer continuously covers the pixel defining portion and the plurality of light-emitting structures. The second carrier layer will not be eroded by water and oxygen in the atmosphere, thereby ensuring good transmission performance of the second carrier layer, and improving the usage performance of the display panel.

### CROSS-REFERENCE TO RELATED APPLICATIONS

The present application claims priority to the Chinese Patent Application No. 202411005511.2, filed on Jul. 25, 2024, and the entire contents of the aforementioned application are hereby incorporated by reference in its entirety.

### FIELD

The present application relates to the field of display technology, and in particular, to a display panel, a display device, and a preparation method for a display panel.

### BACKGROUND

Organic light-emitting displays (OLEDs) as well as flat panel display devices based on technologies such as light-emitting diodes (LEDs) have been widely applied in various consumer electronics such as mobile phones, televisions, laptop computers, and desktop computers due to their advantages such as high image quality, energy efficiency, slim design, and wide applications, making them mainstream in display devices.

However, the usage performance of conventional OLED display products needs to be improved.

### SUMMARY

An objective of the present application is to provide a display panel, a display device, and a preparation method for a display panel to improve the usage performance of the display panel.

A first aspect of the present application provides a display panel. The display panel includes a substrate, a pixel define layer, and a light-emitting device layer. The pixel define layer is disposed on one side of the substrate. The pixel define layer includes a pixel defining portion and a plurality of pixel openings provided in the pixel defining portion. The light-emitting device layer includes a plurality of first carrier structures, a plurality of light-emitting structures, and a second carrier layer. The first carrier structures and the light-emitting structures are located at positions of corresponding pixel openings. The light-emitting structures are located on one side of corresponding first carrier structures, the side facing away from the substrate. The second carrier layer continuously covers the pixel defining portion and the plurality of light-emitting structures.

In some embodiments, the second carrier layer includes a first transport layer. The light-emitting device layer further includes a first electrode layer. The first electrode layer is located on one side of the second carrier layer, the side facing away from the substrate.

In one embodiment, orthographic projections of the pixel defining portion and the plurality of light-emitting structures on the substrate are within an orthographic projection of the first electrode layer on the substrate.

In one embodiment, the first transport layer is an electron transport layer.

In one embodiment, the first electrode layer is a cathode layer.

In some embodiments, the light-emitting device layer further includes at least one first blocking structure. The first blocking structure is located between the second carrier layer and a corresponding light-emitting structure.

In one embodiment, the at least one first blocking structure includes a plurality of first blocking structures one-to-one corresponding to the plurality of light-emitting structures.

In one embodiment, the first blocking structure is a hole blocking structure.

In some embodiments, the second carrier layer further includes a first blocking layer. The first blocking layer is located between the first transport layer and the plurality of light-emitting structures.

In one embodiment, the first blocking layer continuously covers the pixel defining portion and the plurality of light-emitting structures.

In one embodiment, the first blocking layer is a hole blocking layer.

In some embodiments, at least one of the plurality of light-emitting structures includes a first sub-structure and a second sub-structure.

The first sub-structure is located on one side of a corresponding first carrier structure, the side facing away from the substrate. The first sub-structure includes a host material and a dopant material.

The second sub-structure is located between the first sub-structure and the second carrier layer. The second sub-structure includes the host material.

In one embodiment, the second sub-structure does not include the dopant material.

In one embodiment, the plurality of light-emitting structures include a blue light-emitting structure. The blue light-emitting structure includes the first sub-structure and the second sub-structure.

In one embodiment, the plurality of light-emitting structures further include a red light-emitting structure and/or a green light-emitting structure, where the red light-emitting structure includes the first sub-structure and the second sub-structure; and/or the green light-emitting structure includes the first sub-structure and the second sub-structure.

In one embodiment, the second carrier layer further includes a first blocking layer. The first blocking layer is located between the first transport layer and the plurality of light-emitting structures.

In one embodiment, the first blocking layer continuously covers the pixel defining portion and the plurality of light-emitting structures.

In one embodiment, the first blocking layer is a hole blocking layer.

In one embodiment, a thickness of the second sub-structure is D1, which satisfies:

$$20 nm ⩽ D 1 ⩽ 50 nm .$$

In some embodiments, the light-emitting device layer further includes at least one first blocking structure. The first blocking structure is located between the second carrier layer and a corresponding light-emitting structure. The second carrier layer further includes a first blocking layer. The first blocking layer continuously covers the pixel defining portion, the plurality of light-emitting structures, and the at least one first blocking structure.

In one embodiment, a thickness of the first blocking structure is greater than a thickness of the first blocking layer.

In one embodiment, the at least one first blocking structure includes a plurality of first blocking structures one-to-one corresponding to the plurality of light-emitting structures. The first blocking layer continuously covers the pixel defining portion and the plurality of first blocking structures.

In one embodiment, the first blocking structure is a hole blocking structure.

In one embodiment, the first blocking layer is a hole blocking layer.

In one embodiment, the thickness of the first blocking structure is D2, which satisfies: 23 angstroms≤D2≤40 angstroms.

In one embodiment, the thickness of the first blocking layer is D3, which satisfies: 10 angstroms≤D3≤25 angstroms.

In some embodiments, the light-emitting device layer further includes a plurality of second electrodes. Each of the second electrodes is located between the substrate and a corresponding first carrier structure and is partially covered by the pixel defining portion.

In one embodiment, the second carrier layer further includes a first injection layer. The first injection layer is located between the first transport layer and the first electrode layer.

In one embodiment, the first injection layer is an electron injection layer.

In one embodiment, at least one of the plurality of first carrier structures includes a second blocking structure. The second blocking structure is an electron blocking structure.

In one embodiment, at least one of the plurality of first carrier structures includes a second transport structure. The second transport structure is a hole transport structure.

In one embodiment, at least one of the plurality of first carrier structures includes a second injection structure. The second injection structure is a hole injection structure.

According to a second aspect, an embodiment of the present application further provides a preparation method for a display panel. The preparation method includes:
forming a pixel define layer on one side of a substrate, where the pixel define layer includes a pixel defining portion and a plurality of pixel openings provided in the pixel defining portion;
sequentially forming, at positions of corresponding pixel openings, a plurality of first carrier structures, a plurality of light-emitting structures, a plurality of sacrificial structures, and a plurality of masking structures;
sequentially removing the plurality of masking structures and the plurality of sacrificial structures; and
forming a second carrier layer that continuously covers the pixel defining portion and the plurality of light-emitting structures.

In some embodiments, the second carrier layer includes a first transport layer. After the step of forming the second carrier layer that continuously covers the pixel defining portion and the plurality of light-emitting structures, the method further includes:
forming a first electrode layer on one side of the second carrier layer, the side facing away from the substrate.

In one embodiment, the first transport layer is an electron transport layer, and/or the first electrode layer is a cathode layer.

In one embodiment, each of the sacrificial structures includes a first sub-sacrificial structure and a second sub-sacrificial structure disposed sequentially along a direction away from the substrate. A material of the first sub-sacrificial structure includes a water-soluble resin. A material of the second sub-sacrificial structure includes an inorganic material.

In some embodiments, the plurality of pixel openings include a first pixel opening and a second pixel opening. The step of sequentially forming, at the positions of corresponding pixel openings, the plurality of first carrier structures, the plurality of light-emitting structures, the plurality of sacrificial structures, and the plurality of masking structures includes:
sequentially forming a first carrier material layer, a first light-emitting material layer, and a sacrificial material layer along a direction away from the substrate;
forming a masking structure on one side of the sacrificial material layer, the side facing away from the substrate, where an orthographic projection of the masking structure on the substrate covers an orthographic projection of the first pixel opening on the substrate; removing, by using the masking structure as a mask, the sacrificial material layer, the first light-emitting material layer, and the first carrier material layer that are located in the second pixel opening and located on one side of the pixel defining portion that faces away from the substrate to obtain a first carrier structure, a first light-emitting structure, and a sacrificial structure that are located at a position of the first pixel opening; and forming a first carrier structure, a second light-emitting structure, and a sacrificial structure that are located at a position of the second pixel opening.

In some embodiments, the step of sequentially forming the first carrier material layer, the first light-emitting material layer, and the sacrificial material layer along the direction away from the substrate includes: sequentially forming the first carrier material layer, the first light-emitting material layer, a first blocking material layer, and the sacrificial material layer along the direction away from the substrate; and
the step of obtaining the first carrier structure, the first light-emitting structure, and the sacrificial structure that are located at the position of the first pixel opening includes: removing, by using the masking structure as a mask, the sacrificial material layer, the first light-emitting material layer, the first blocking material layer, and the first carrier material layer that are located in the second pixel opening and located on one side of the pixel defining portion that faces away from the substrate to obtain a first carrier structure, a first light-emitting structure, a first blocking structure, and a sacrificial structure that are located at the position of the first pixel opening.

In one embodiment, the first blocking structure is a hole blocking structure.

In some embodiments, the step of forming the second carrier layer that continuously covers the pixel defining portion and the plurality of light-emitting structures includes:
sequentially forming a first blocking layer and a first transport layer that continuously cover the pixel defining portion, the first light-emitting structure, and the second light-emitting structure.

In one embodiment, the first blocking layer is a hole blocking layer, and/or the first transport layer is an electron transport layer.

In some embodiments, the first light-emitting material layer includes a first sub-material layer and a second sub-material layer that are sequentially stacked along the direction away from the substrate. The step of obtaining the first carrier structure, the first light-emitting structure, and the sacrificial structure that are located at the position of the first pixel opening includes:
removing, by using the masking structure as a mask, the sacrificial material layer, the second sub-material layer, the first sub-material layer, and the first carrier material layer that are located in the second pixel opening and located on one side of the pixel defining portion that faces away from the substrate to obtain a first carrier structure, a first light-emitting structure, and a sacrificial structure that are located at the position of the first pixel opening.

The first light-emitting structure includes a first sub-structure and a second sub-structure that are sequentially stacked along the direction away from the substrate. The first sub-structure includes a host material and a dopant material, and the second sub-structure includes the host material.

In one embodiment, the second sub-structure does not include the dopant material.

In one embodiment, the first light-emitting structure is a blue light-emitting structure.

In some embodiments, the step of sequentially forming the first carrier material layer, the first light-emitting material layer, and the sacrificial material layer along the direction away from the substrate includes: sequentially forming the first carrier material layer, the first light-emitting material layer, a first blocking material layer, and the sacrificial material layer along the direction away from the substrate; and
the step of obtaining the first carrier structure, the first light-emitting structure, and the sacrificial structure that are located at the position of the first pixel opening includes: removing, by using the masking structure as a mask, the sacrificial material layer, the first light-emitting material layer, the first blocking material layer, and the first carrier material layer that are located in the second pixel opening and located on one side of the pixel defining portion that faces away from the substrate to obtain a first carrier structure, a first light-emitting structure, a first blocking structure, and a sacrificial structure that are located at the position of the first pixel opening.

The step of forming the second carrier layer that continuously covers the pixel defining portion and the plurality of light-emitting structures includes: sequentially forming a first blocking layer and a first transport layer that continuously cover the pixel defining portion, the first light-emitting structure, and the second light-emitting structure.

In one embodiment, the first blocking structure is a hole blocking structure, and/or the first blocking layer is a hole blocking layer, and/or the first transport layer is an electron transport layer.

According to a third aspect, the present application further provides a display device. The display device includes the display panel or a display panel prepared by using any one of the preparation methods described above.

Embodiments of the present application provide a display panel, a display device, and a preparation method for a display panel. The display panel includes a substrate, a pixel define layer, and a light-emitting device layer. The pixel define layer is disposed on one side of the substrate. The pixel define layer includes a pixel defining portion and a plurality of pixel openings provided in the pixel defining portion. The light-emitting device layer includes a plurality of first carrier structures, a plurality of light-emitting structures, and a second carrier layer. The first carrier structures and the light-emitting structures are located at positions of corresponding pixel openings. The light-emitting structures are located on one side of corresponding first carrier structures, the side facing away from the substrate. The second carrier layer continuously covers the pixel defining portion and the plurality of light-emitting structures. In preparation of a display panel, the first carrier structure and the light-emitting structure may be prepared first by using a sacrificial structure and a masking structure, and then a second carrier layer is formed by full-surface evaporation. The second carrier layer will not be eroded by water and oxygen in the atmosphere, thereby ensuring good transmission performance of the second carrier layer, and improving the usage performance of the display panel.

### BRIEF DESCRIPTION OF THE DRAWINGS

In order to describe the embodiments of the disclosure more clearly, the drawings required for illustration of the embodiments of the disclosure will be briefly introduced below. The drawings as described below are only for some of the embodiments of the disclosure, and other drawings can also be obtained from these drawings.

FIG. 1 is a schematic cross-sectional view of a display panel according to some embodiments of the present application;

FIG. 2 is a schematic cross-sectional view of a display panel according to some other embodiments of the present application;

FIG. 3 is a schematic cross-sectional view of a display panel according to still other embodiments of the present application;

FIG. 4 is a partial schematic cross-sectional view of a display panel according to some embodiments of the present application;

FIG. 5 is a schematic cross-sectional view of a display panel according to still other embodiments of the present application;

FIG. 6 is a schematic cross-sectional view of a display panel according to yet other embodiments of the present application;

FIG. 7 is a schematic cross-sectional view of a display panel according to yet other embodiments of the present application;

FIG. 8 is a schematic cross-sectional view of a display panel according to yet other embodiments of the present application;

FIG. 9 is a schematic flowchart of a preparation method for a display panel according to some embodiments of the present application;

FIG. 10 is a schematic process diagram of step S10 of the preparation method for a display panel according to some embodiments of the present application;

FIG. 11 is a schematic process diagram of step S20 of the preparation method for a display panel according to some embodiments of the present application;

FIG. 12 is a schematic process diagram of step S30 of the preparation method for a display panel according to some embodiments of the present application;

FIG. 13 is a schematic process diagram of step S40 of the preparation method for a display panel according to some embodiments of the present application;

FIG. 14 is a partial schematic process diagram of the preparation method for a display panel according to some embodiments of the present application; and

FIG. 15a to FIG. 15k are schematic process diagrams of preparation of a display panel according to some embodiments of the present application.

### LIST OF REFERENCE SIGNS

100. display panel; 10. substrate; 20. pixel define layer; 21. pixel defining portion; 22. pixel opening; 221. first pixel opening; 222. second pixel opening; 223. third pixel opening; 30. light-emitting device layer; 31. second electrode; 32. first carrier structure; 321. second injection structure; 322. second transport structure; 323. first carrier material layer; 33. light-emitting structure; 331. first sub-structure; 332. second sub-structure; 333. first light-emitting structure; 334. second light-emitting structure; 335. third light-emitting structure; 336. first light-emitting material layer; 337. second light-emitting material layer; 338. third light-emitting material layer; 34. second carrier layer; 341. second injection layer; 342. first transport layer; 35. first electrode layer; 36. second blocking structure; 37. first blocking structure; 371. first blocking material layer; 38. first blocking layer; 40. sacrificial structure; 41. first sub-sacrificial structure; 42. second sub-sacrificial structure; 43. sacrificial material layer; 50. masking structure; 51. blocking material layer.

### DETAILED DESCRIPTION OF THE EMBODIMENTS

The implementations of the present application are further described in detail below with reference to the accompanying drawings and embodiments. The following detailed description of the embodiments and the accompanying drawings are used to illustrate the principle of the present application in an exemplary manner, but shall not be used to limit the scope of the present application. That is, the present application is not limited to the described embodiments.

An embodiment of the present application provides a display panel. The display panel may be an organic light-emitting diode (OLED) display panel, or another type of display panel, such as a micro light-emitting diode (Micro-LED) display panel or a quantum dot light-emitting diode (QLED) display panel.

As shown in FIG. 1, a first aspect of the present application provides a display panel 100. The display panel 100 includes a substrate 10, a pixel define layer 20, and a light-emitting device layer 30. The pixel define layer 20 is disposed on one side of the substrate 10. The pixel define layer 20 includes a pixel defining portion 21 and a plurality of pixel openings 22 provided in the pixel defining portion 21. The light-emitting device layer 30 includes a plurality of first carrier structures 32, light-emitting structures 33, and a second carrier layer 34. The first carrier structures 32 and the light-emitting structures 33 are located at positions of corresponding pixel openings 22. The light-emitting structures 33 are located on one side of corresponding first carrier structures 32, the side facing away from the substrate 10. The second carrier layer 34 continuously covers the pixel defining portion 21 and the plurality of light-emitting structures 33.

The substrate 10 includes a substrate and an array layer disposed on the substrate. The substrate may be a rigid substrate made of glass, plastic, or another material, or a flexible substrate made of polyethersulfone (PES), polyacrylate (PAR), polyetherimide (PEI), polyethylene naphthalate (PEN), polyethylene terephthalate (PET), polyphenylene sulfide (PPS), polyarylate, polyimide (PI), polycarbonate (PC), cellulose acetate propionate (CAP), or another material. A drive circuit for controlling a light-emitting unit 30 to emit light is disposed in the array layer. The array layer is generally composed of inorganic film layers such as a metal layer, a semiconductor layer (active layer), and an insulation layer. The drive circuit for controlling the light-emitting unit to emit light may be formed by patterning these inorganic film layers, and there may be various implementations of the specific circuit structure of the drive circuit, which will not be described in detail herein.

The pixel defining portion 21 may cover the edge of the second electrode 31 to increase the area of the sub-pixel. The pixel defining portion 21 can reduce crosstalk between the first carrier structure 32 and the light-emitting structure 33 of each sub-pixel, and improve the display effect of the display panel 100.

During preparation of the display panel 100, it is necessary to use a masking structure 50 when patterning the light-emitting structure 33 of each sub-pixel. Because the masking structure 50 contains a solvent, if the masking structure 50 is prepared directly on the light-emitting structure 33, the solvent in the masking structure 50 dissolves an underlying film layer. Therefore, a sacrificial material layer 43 is prepared first, and then the masking structure 50 is prepared on the sacrificial material layer 43. A first carrier material layer 323, a first light-emitting material layer 336, a sacrificial material layer 43, and a masking material layer 51 of a first sub-pixel may be first sequentially deposited by full-surface evaporation, and the masking material layer 51 may be treated by an exposure and development process to form a masking structure 50 corresponding to the first pixel opening 221. Subsequently, by using the masking structure 50 as a mask, the sacrificial material layer 43, the first light-emitting material layer 336, and the first carrier material layer 323 beyond the first pixel opening 221 may be removed to obtain a first carrier structure 32, a first light-emitting structure 333, and a sacrificial structure 40 that are located at the position of the first pixel opening 221. Subsequently, a first carrier material layer 323, a second dopant material layer 337, a sacrificial material layer 43, and a masking material layer 51 of a second sub-pixel are deposited by full-surface evaporation, and the masking material layer 51 is treated by an exposure and development process to form a masking structure 50 corresponding to the second pixel opening 222. Subsequently, by using the masking structure 50 as a mask, the sacrificial material layer 43, the second dopant material layer 337, and the first carrier material layer beyond the second pixel opening 222 are removed to obtain a first carrier structure 32, a second light-emitting structure 334, and a sacrificial structure 40 that are located at the position of the second pixel opening 222. Finally, a first carrier material layer 323, a third dopant material layer 338, a sacrificial material layer 43, and a masking material layer 51 of a third sub-pixel may be deposited by full-surface evaporation, and the masking material layer 51 may be treated by an exposure and development process to form a masking structure 50 corresponding to the third pixel opening 223. Subsequently, by using the masking structure 50 as a mask, the sacrificial material layer 43, the third dopant material layer 338, and the second carrier material layer beyond the third pixel opening 223 may be removed to obtain a first carrier structure 32, a third light-emitting structure 335, and a sacrificial structure 40 that are located at the position of the third pixel opening 223. Subsequently, the masking structure 50 and the sacrificial structure 40 of the first sub-pixel, the second sub-pixel, and the third sub-pixel are stripped off, and the second carrier layer 34 and the first electrode layer 35 are deposited by full-surface evaporation.

That the first carrier structure 32 and the light-emitting structure 33 are located at the position of the pixel opening 22 means that a part of the first carrier structure 32 and the light-emitting structure 33 may be located within the pixel opening 22 and another part thereof may be located on one side of the pixel defining portion 21, the side facing away from the substrate 10. Because the second carrier layer 34 and the first electrode layer 35 are not patterned but are formed by a full-surface evaporation process, the second carrier layer 34 and the first electrode layer 35 are of continuous full-layer design.

The second carrier layer 34 is hydrophilic to some extent, and a film layer thereof is hardly resistant to water, oxygen, and an organic solvent. In this embodiment of the present application, after the light-emitting structure 33 of each sub-pixel is patterned, the second carrier layer 34 is formed by full-surface evaporation. The light-emitting structure 33 is hydrophobic to some extent, and can block a part of moisture from penetrating into the film layer. Therefore, the second carrier layer 34 will not be eroded by water and oxygen in the atmosphere, thereby ensuring good transmission performance of the second carrier layer 34, and improving the usage performance of the display panel 100. Moreover, during patterning by use of the sacrificial structure 40, the sacrificial structure 40 is generally a water-soluble resin. The second carrier layer 34, which itself is hydrophilic to some extent, is formed only after the sacrificial structure 40 is removed. Therefore, moisture of the sacrificial structure 40 does not penetrate into the film layer, thereby further improving the performance of the display panel 100.

In some embodiments, the second carrier layer 34 includes a first transport layer 342. The light-emitting device layer 30 further includes a first electrode layer 35. The first electrode layer 35 is located on one side of the second carrier layer 34, the side facing away from the substrate 10.

In some embodiments, the light-emitting device layer 30 further includes a plurality of second electrodes 31. Each of the second electrodes 31 is located between the substrate 10 and a corresponding first carrier structure 32 and is partially covered by the pixel defining portion 21.

Of the second electrode 31 and the first electrode layer 35, one may serve as an anode of the sub-pixel and the other as a cathode of the sub-pixel. An embodiment of the present application is described by using an example in which the second electrode 31 serves as the anode of the sub-pixel and the first electrode layer 35 as the cathode of the sub-pixel. When the second electrode 31 is an anode and the first electrode layer 35 is a cathode, the first carrier structure 32 includes a hole transport structure, and the second carrier layer 34 includes an electron transport layer. When the second electrode 31 and the first electrode layer 35 are energized, electrons and holes migrate from the electron transport layer and the hole transport structure, respectively, to the light-emitting structure 33, and meet in the light-emitting structure 33 to form excitons that excite light-emitting molecules, thereby generating visible light for the purpose of display.

In one embodiment, orthographic projections of the pixel defining portion 21 and the plurality of light-emitting structures 33 on the substrate 10 are within an orthographic projection of the first electrode layer 35 on the substrate 10.

The first electrode layer 35 covers the pixel defining portion 21 and the light-emitting structure 33, so that the light-emitting structure 33 of each sub-pixel can be supplied with a uniform current, thereby ensuring uniform brightness throughout the display panel, and avoiding uneven brightness or local speckle.

In one embodiment, the first transport layer 342 is an electron transport layer. A primary function of the first transport layer 342 is to efficiently transport injected electrons so that the electrons can reach the light-emitting structure 33 smoothly. The first transport layer 342 exhibits a high electron mobility, allowing the electrons to be transported quickly and efficiently.

In one embodiment, the first transport layer is a cathode layer.

In other words, the display panel in this embodiment of the present application is a top light-emitting structure, thereby reducing absorption inside a dopant material, improving overall light output efficiency, and moreover, controlling the direction and wavelength of light more effectively, and improving color purity and contrast.

In some embodiments, a part of the second carrier layer 34 is located within the pixel opening 22, and another part thereof is located on one side of the pixel defining portion 21, the side facing away from the substrate 10.

A surface of the pixel defining portion 21 that faces away from the substrate 10 is higher than a surface of the light-emitting structure 33. Therefore, when the second carrier layer 34 is deposited by full-surface evaporation, a part of the material of the second carrier layer 34 is deposited within the pixel opening 22 and located on one side of the light-emitting structure 33, the side facing away from the substrate 10. Another part thereof is deposited outside the pixel opening 22 and located on one side of the pixel defining portion 21, the side facing away from the substrate 10. The second carrier layer 34 does not need to be patterned. The first electrode layer 35 may be directly prepared on the second carrier layer 34, thereby preventing the second carrier layer 34 from being exposed to moisture and a solvent in the sacrificial structure 40, alleviating the problem of electron injection difficulty caused by damage to the second carrier layer 34, and reducing voltage of the device.

In some embodiments, the part of the second carrier layer 34 within the pixel opening 22 is in contact with an inner wall of the pixel defining portion 21, the inner wall facing the pixel opening 22.

The second carrier layer 34 is formed as a full layer, covers not only the side of the first light-emitting structure 33 that faces away from the substrate 10, but also the inner wall of the pixel defining portion 21 that faces the pixel opening 22, and climbs along the inner wall of the pixel defining portion 21 to reach an upper surface of the pixel defining portion 21. The second carrier layer 34 is used as an interlayer to fully separate the first electrode layer 35 from the second electrode 31, thereby preventing the first electrode layer 35 from being shorted to a lateral edge of the second electrode 31 by contact.

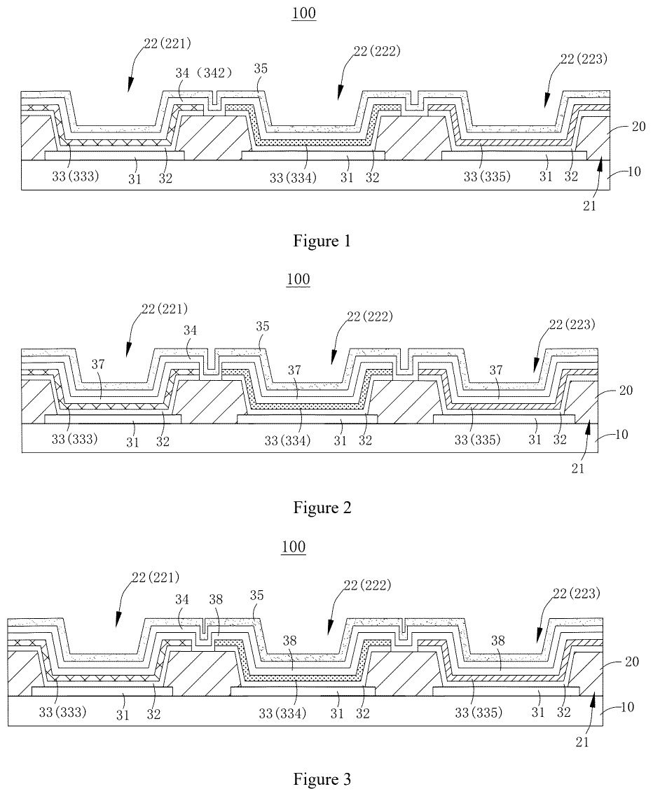

As shown in FIG. 2, in some embodiments, the display panel 100 further includes at least one first blocking structure 37. The first blocking structure 37 is disposed between the light-emitting structure 33 and the second carrier layer 34.

The first blocking structure 37 can block carriers from the second electrode 31 at an interface of the light-emitting structure 33, thereby increasing the concentration of the carriers at the interface of the light-emitting structure 33.

In one embodiment, the at least one first blocking structure 37 includes a plurality of first blocking structures 37 one-to-one corresponding to the plurality of light-emitting structures 33.

In other words, one first blocking structure 37 is disposed on each light-emitting structure 33, and an orthographic projection of each first blocking structure 37 on the substrate 10 at least partially overlaps an orthographic projection of the light-emitting structure 33 below the first blocking structure on the substrate 10.

A part of the first blocking structure 37 may be located within the pixel opening 22, and another part thereof may be located on one side of the pixel defining portion 21, the side facing away from the substrate 10.

A first carrier material layer 323, a first light-emitting material layer 336, a first blocking material layer 371, a sacrificial material layer 43, and a masking material layer 51 of a first sub-pixel may be first sequentially deposited by full-surface evaporation, and the masking material layer 51 may be treated by an exposure and development process to form a masking structure 50 corresponding to the first pixel opening 221. Subsequently, by using the masking structure 50 as a mask, the sacrificial material layer 43, the first blocking material layer 371, the first light-emitting material layer 336, and the first carrier material layer 323 beyond the first pixel opening 221 may be removed to obtain a first carrier structure 32, a first light-emitting structure 333, a first blocking structure 37, and a sacrificial structure 40 that are located at the position of the first pixel opening 221. Subsequently, a first carrier material layer 323, a second dopant material layer 337, a first blocking material layer 371, a sacrificial material layer 43, and a masking material layer 51 of a second sub-pixel are deposited by full-surface evaporation, and the masking material layer 51 is treated by an exposure and development process to form a masking structure 50 corresponding to the second pixel opening 222. Subsequently, by using the masking structure 50 as a mask, the sacrificial material layer 43, the first blocking material layer 371, the second dopant material layer 337, and the second carrier material layer beyond the second pixel opening 222 are removed to obtain a first carrier structure 32, a second light-emitting structure 334, a first blocking structure 37, and a sacrificial structure 40 that are located at the position of the second pixel opening 222. Finally, a first carrier material layer 323, a third dopant material layer 338, a first blocking material layer 371, a sacrificial material layer 43, and a masking material layer 51 of a third sub-pixel may be deposited by full-surface evaporation, and the masking material layer 51 may be treated by an exposure and development process to form a masking structure 50 corresponding to the third pixel opening 223. Subsequently, by using the masking structure 50 as a mask, the sacrificial material layer 43, the first blocking material layer 371, the third dopant material layer 338, and the second carrier material layer beyond the third pixel opening 223 may be removed to obtain a first carrier structure 32, a third light-emitting structure 335, a first blocking structure 37, and a sacrificial structure 40 that are located at the position of the third pixel opening 223. Subsequently, the masking structure 50 and the sacrificial structure 40 of the first sub-pixel, the second sub-pixel, and the third sub-pixel are stripped off, and the second carrier layer 34 and the first electrode layer 35 are deposited by full-surface evaporation.

In these embodiments of the present application, the sacrificial structure 40 is prepared on the first blocking structure 37. Because the first blocking structure 37 is hydrophobic to some extent, the first blocking structure 37 can block a part of moisture from penetrating into the film layer, thereby reducing erosion of an underlying film layer caused by the moisture in the atmosphere and a solvent in the sacrificial structure 40.

In one embodiment, the first blocking structure 37 is a hole blocking structure.

Therefore, the first blocking structure 37 can block holes from the second electrode 31 at an interface of the light-emitting structure 33, thereby increasing the concentration of holes at the interface of the light-emitting structure 33.

As shown in FIG. 3, in some other embodiments, the second carrier layer 34 further includes a first blocking layer 38. The first blocking layer 38 is located between the first transport layer 342 and the plurality of light-emitting structures 33.

After the sacrificial structure 40 and the masking structure 50 are prepared on the

light-emitting structures 33 and then patterned, the first blocking layer 38 and the second carrier layer 34 are prepared. In patterning each sub-pixel, the first blocking layer 38 does not need to be removed by an etching process, thereby reducing the process difficulty.

In one embodiment, the first blocking layer 38 continuously covers the pixel defining portion 21 and the plurality of light-emitting structures 33. The first blocking layer 38 is formed as a full layer by full-surface evaporation, and covers the pixel defining portion 21, thereby being able to more thoroughly blocking carriers from the second electrode 31 at the interface of the light-emitting structures 33.

In one embodiment, the first blocking layer 38 is a hole blocking layer.

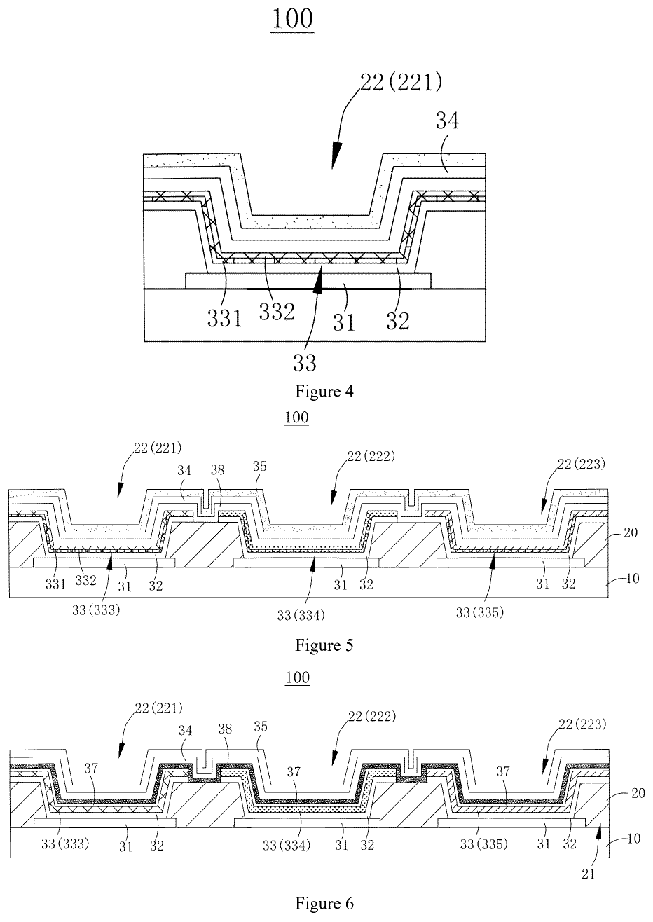

As shown in FIG. 4, in some embodiments, at least one of the plurality of light-emitting structures 33 includes a first sub-structure 331 and a second sub-structure 332, where the first sub-structure 331 is located on one side of a corresponding first carrier structure 32, the side facing away from the substrate 10. The first sub-structure 331 includes a host material and a dopant material. The second sub-structure 332 is located between the first sub-structure 331 and the second carrier layer 34. The second sub-structure 332 includes a host material.

All the light-emitting structures 33 may be configured to include the first sub-structure 331 and the second sub-structure 332, or only some of the light-emitting structures 33 may be configured to include the first sub-structure 331 and the second sub-structure 332.

The host material is mainly configured to carry the dopant material and promote effective transfer of carriers in a transport layer and of energy. The host material itself does not emit light, but functions to provide a suitable environment for the dopant material to work efficiently. The host material may include small-molecule organic compounds, polymer materials, and the like, such as CBP (4,4′-bis(N-carbazolyl)biphenyl), TCTA (tris(4-aminophenyl)amine), mCP (1,3-bis (N-carbazolyl)benzene), and TAD (4,4′-bis (9H-carbazol-9-yl)benzophenone), PVK (poly(N-vinylcarbazole)), and PFO (poly(9,9-dioctylfluorene)).

The dopant material is responsible for recombination of charge carriers and emitting visible light. Such materials directly determine the light-emission color and efficiency of sub-pixels, and include two major categories: fluorescent materials and phosphorescent materials.

In an embodiment of the present application, one layer of first sub-structure 331 is prepared first, which contains both a host material and a dopant material; and then one layer of second sub-structure 332 is prepared, which may contain only a host material but no dopant material, or may contain both a host material and a dopant material. After patterning is performed by etching, a first blocking structure 37 and a second carrier layer 34 are deposited by evaporation. Although the dopant material is susceptible to erosion by water and oxygen, the second sub-structure 332 protects the dopant material in the first sub-structure 331 against erosion interference, thereby improving the light-emission efficiency of the light-emitting structure 33.

In one embodiment, the second sub-structure 332 includes no dopant material, thereby making the preparation of the second sub-structure 332 simpler.

In one embodiment, the plurality of light-emitting structures 33 include a blue light-emitting structure. The blue light-emitting structure includes the first sub-structure 331 and the second sub-structure 332. Because a blue light-emitting structure is not resistant but sensitive to moisture, this design is particularly effective for blue light-emitting structures.

In one embodiment, the plurality of light-emitting structures 33 further include a red light-emitting structure and/or a green light-emitting structure, where the red light-emitting structure includes the first sub-structure 331 and the second sub-structure 332; and/or the green light-emitting structure includes the first sub-structure 331 and the second sub-structure 332.

The second sub-structure 332 of the red light-emitting structure protects the dopant material in the first sub-structure 331 thereof, and/or the second sub-structure 332 of the green light-emitting structure protects the dopant material in the first sub-structure 331 thereof, thereby further improving the light emission efficiency of more light-emitting structures 33.

As shown in FIG. 5, in one embodiment, the second carrier layer 34 further includes a first blocking layer 38. The first blocking layer 38 is located between the first transport layer 342 and the plurality of light-emitting structures 33. In one embodiment, the first blocking layer 38 is located between the second sub-structure 332 and the first transport layer 342.

In one embodiment, the first blocking layer 38 continuously covers the pixel defining portion 21 and the plurality of light-emitting structures 33. In one embodiment, the first blocking layer 38 is a hole blocking layer.

In some embodiments, the thickness of the second sub-structure 332 is D1, which satisfies: 20 nm≤D1≤50 nm.

D1 may be any value ranging from 20 nm to 50 nm. For example, D1 may be 20 nm, 25 nm, 30 nm, 40 nm, 45 nm, 50 nm, or the like, as long as the value falls within the range of 20 nm to 50 nm.

In these embodiments of the present application, the second sub-structure 332 is of a moderate thickness, thereby reducing the vulnerability of the dopant material in the first sub-structure 331 to erosion caused by water, oxygen, and solvents without affecting the placement of other film layers.

As shown in FIG. 6, the light-emitting device layer 30 further includes at least one first blocking structure 37. The first blocking structure 37 is located between the second carrier layer 34 and a corresponding light-emitting structure 33. The second carrier layer 33 further includes a first blocking layer 38. The first blocking layer 38 continuously covers the pixel defining portion 21, the plurality of light-emitting structures 33, and the at least one first blocking structure 37.

Due to the sacrificial structure 40 applied to different film layers of the display panel 100, the device effects vary greatly. If the sacrificial structure 40 is applied after the first blocking structure 37 is deposited by evaporation, the interface of the first blocking structure 37 after photolithographic patterning is damaged. The damaged interface is located at an interface between the first blocking structure 37 and the second carrier layer 34. The difficulty of transport of carriers from the second carrier layer 34 to the first blocking structure 37 is increased, a device voltage rises significantly, and performance deteriorates severely. In embodiments of the present application, the first blocking layer 38 is prepared on the first blocking structure 37. During patterning of each sub-pixel, the sacrificial structure 40 is located on the first blocking structure 37. After the masking structure 50 and the sacrificial structure 40 are finally removed, the first blocking layer 38 is formed by full-surface evaporation. The damaged interface is the interface between the first blocking structure 37 and the first blocking layer 38, which is inside the same material. The contact interface between different materials is not damaged, and little impact is caused to the transport of carriers.

In some embodiments, the thickness of the first blocking structure 37 is greater than the thickness of the first blocking layer 38 along a direction perpendicular to the substrate 10.

By making the first blocking structure 37 thicker, the first blocking structure 37 does not affect the underlying film layer even if it is damaged by the sacrificial structure 40

In one embodiment, the at least one first blocking structure 37 includes a plurality of first blocking structures 37 one-to-one corresponding to the plurality of light-emitting structures 33. The first blocking layer 38 continuously covers the pixel defining portion 21 and the plurality of first blocking structures 37.

In some embodiments, along a direction perpendicular to the substrate 10, the thickness of the first blocking structure 37 is D2, which satisfies: 23 angstroms≤D2≤40 angstroms.

D2 may be any value ranging from 23 angstroms to 40 angstroms. For example, D2 may be 23 angstroms, 25 angstroms, 30 angstroms, 35 angstroms, 38 angstroms, 40 angstroms, or the like, as long as the value falls within the range of 23 angstroms to 40 angstroms.

In these embodiments of the present application, the thickness of the first blocking structure 37 is moderate, thereby protecting the underlying film against damage and avoiding occupation of space of other film layers.

In some embodiments, along a direction perpendicular to the substrate 10, the thickness of the first blocking layer 38 is D3, which satisfies: 10 angstroms≤D3≤25 angstroms.

D3 may be any value ranging from 10 angstroms to 25 angstroms. For example, D3 may be 10 angstroms, 15 angstroms, 18 angstroms, 20 angstroms, 23 angstroms, 25 angstroms, or the like, as long as the value falls within the range of 10 angstroms to 25 angstroms.

In these embodiments of the present application, the thickness of the first blocking layer 38 is moderate, thereby blocking electrons or holes without occupying space in other film layers.

In some embodiments, the second carrier layer 34 further includes a first injection layer 341. The first injection layer 341 is disposed between the first transport layer 342 and the first electrode layer 35.

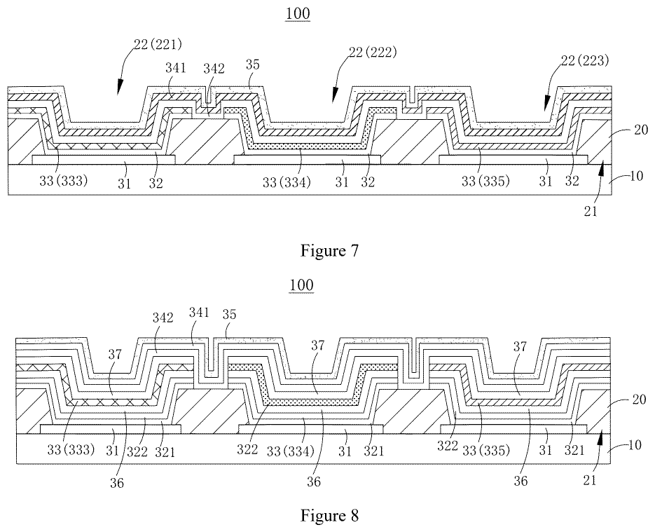

As shown in FIG. 7, the first injection layer 341 can reduce an energy barrier between the first electrode layer 35 and the first transport layer 342, and improve the interface matching between the first electrode layer 35 and the light-emitting structure 33, thereby making it easier for carriers to be injected from the first electrode layer 35 into the light-emitting structure 33. By optimizing the interface, the first injection layer 341 improves the efficiency of the carrier injection from the first electrode layer 35 into the light-emitting structure 33, and improves the light-emission efficiency of the display panel 100. In addition, the first injection layer 341 can also improve the stability of the interface between the first electrode layer 35 and the light-emitting structure 33, and reduce interfacial reactions and degradation, thereby extending the lifespan of the display panel 100.

In one embodiment, the first injection layer 341 is an electron injection layer.

As shown in FIG. 8, in some embodiments, at least one of the plurality of first carrier structures 32 includes a second blocking structure 36. The second blocking structure 36 is an electron blocking structure.

The second blocking structure 36 can block electrons from the first electrode layer 35 at an interface of the light-emitting structure 33, thereby increasing the concentration of the electrons at the interface of the light-emitting structure 33.

In one embodiment, at least one of the plurality of first carrier structures 32 includes a second transport structure 322. The second transport structure 322 is a hole transport structure.

The second transport structure 322 functions to transport holes so that the holes can move effectively to the light-emitting structure 33. The second transport structure 322 exhibits a high hole mobility and can transport holes efficiently. By providing a good conductive path, the second transport structure 322 enables the holes to move rapidly to the light-emitting structure 33, thereby improving the efficiency of hole transport and reducing energy loss caused during transport of the holes.

At least one of the plurality of first carrier structures 32 includes a second injection structure 321. The second injection structure 321 is a hole injection structure. The second injection structure 321 is disposed on one side of the second electrode 31, the side facing away from the substrate 10. The second transport structure 322 is disposed between the second injection structure 321 and the light-emitting structure 33.

The second injection structure 321 can reduce an energy level matching barrier between the second electrode 31 and the second transport structure 322. By optimizing the interface between the second electrode 31 and the light-emitting structure 33, the second injection structure enables holes to be more easily injected from the second electrode 31 into the light-emitting structure 33. By reducing the barrier, the second injection structure 321 improves the efficiency of injection of the holes from the second electrode 31 into the light-emitting structure 33, so that more holes can effectively enter the light-emitting structure 33.

In some embodiments, the display panel 100 further includes an encapsulation layer. The encapsulation layer is disposed on one side of the first electrode layer 35, the side facing away from substrate 10. The encapsulation layer covers the pixel defining portion 21.

The encapsulation layer generally includes an inorganic encapsulation layer, an organic encapsulation layer, and another inorganic encapsulation layer that are disposed sequentially in the display panel 100 along a direction away from the substrate 10. The first inorganic encapsulation layer is usually dense and hard, and can effectively block gases and moisture and prevent ingress of external environmental matters such as water vapor and oxygen. The organic encapsulation layer is relatively soft and resilient, with a specified cushioning capacity. The second inorganic encapsulation layer is the same as the first inorganic encapsulation layer, and further enhances the protective properties of the encapsulation layer.

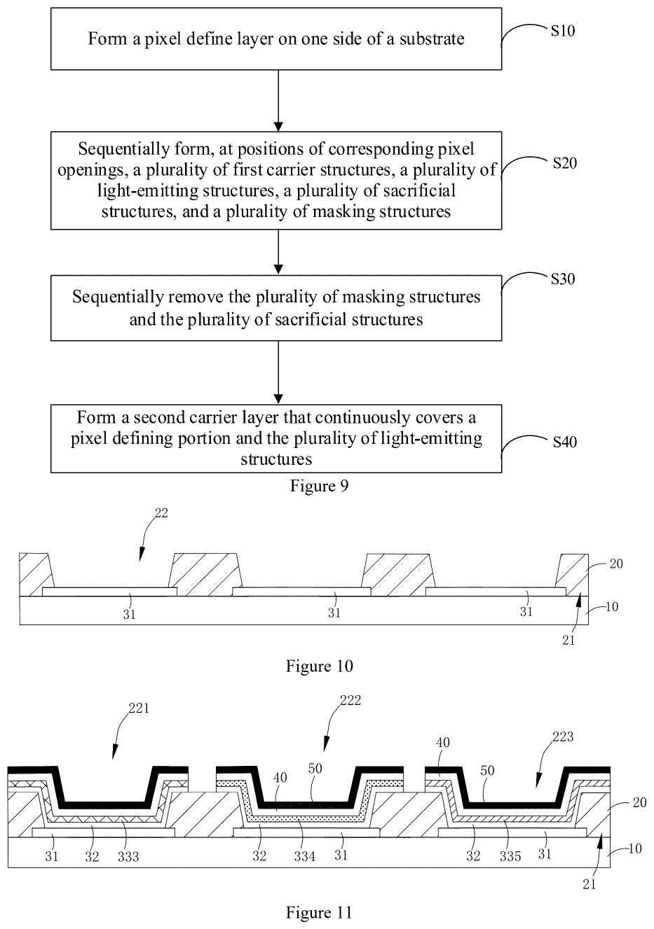

As shown in FIG. 9, according to a third aspect, an embodiment of the present application further provides a preparation method for a display panel 100. The preparation method includes the following steps.

As shown in FIG. 10, in step S10, a pixel define layer 20 is formed on one side of a substrate 10.

Second electrodes 31 may be formed first on one side of the substrate 10, where adjacent second electrodes 31 are spaced apart. A material for the second electrodes 31 may be first deposited by full-surface evaporation, and then the second electrodes 31 spaced apart may be formed by an etching process. Subsequently, the pixel define layer 20 is formed on one side of the substrate 10 that is provided with the second electrodes 31. The pixel define layer 20 includes a pixel defining portion 21 and a pixel opening 22 provided in the pixel defining portion 21. At least a part of the second electrode 31 is exposed from the pixel opening 22. The pixel defining portion 21 may cover the edge of the second electrode 31 to increase the area of the sub-pixel. The pixel defining portion 21 can reduce crosstalk between the first carrier structure 32 and the light-emitting structure 33 of each sub-pixel, and improve the display effect of the display panel 100.

As shown in FIG. 11, in step S20, a plurality of first carrier structures 32, a plurality of light-emitting structures 33, a plurality of sacrificial structures 40, and a plurality of masking structures 50 are sequentially formed at positions of corresponding pixel openings 22.

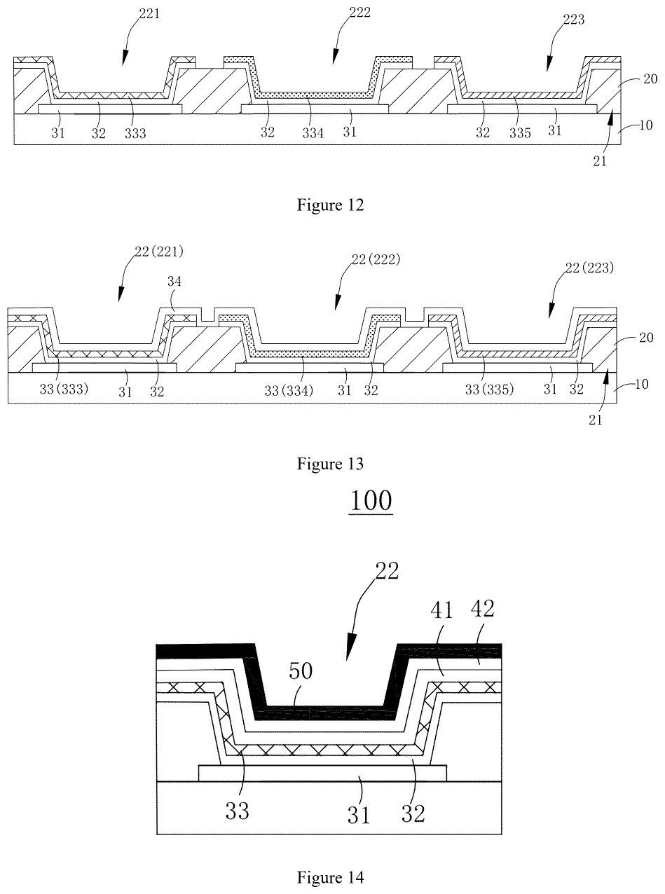

As shown in FIG. 12, in step S30, the plurality of masking structures 50 and the plurality of sacrificial structures 40 are sequentially removed.

As shown in FIG. 13, in step S40, a second carrier layer 34 that continuously covers the pixel defining portion 21 and the plurality of light-emitting structures 33 is formed.

After the light-emitting structure 33 of each sub-pixel is patterned, the second carrier layer 34 is formed by full-surface evaporation. The light-emitting structure 33 is hydrophobic to some extent, and can block a part of moisture from penetrating into the film layer. Therefore, the second carrier layer 34 will not be eroded by water and oxygen in the atmosphere, thereby ensuring good transmission performance of the second carrier layer 34, and improving the usage performance of the display panel 100.

In some embodiments, the second carrier layer 34 includes a first transport layer 342. After the step S40 of forming the second carrier layer 34 that continuously covers the pixel defining portion 21 and the plurality of light-emitting structures 33, the method further includes the following step:
S50: Form a first electrode layer 35 on one side of the second carrier layer 342, the side facing away from the substrate 10.

In one embodiment, the first transport layer 342 is an electron transport layer, and/or the first electrode layer 35 is a cathode layer.

As shown in FIG. 14, in one embodiment, each of the sacrificial structures 40 includes a first sub-sacrificial structure 41 and a second sub-sacrificial structure 42 disposed sequentially along a direction away from the substrate 10. The material of the first sub-sacrificial structure 41 includes a water-soluble resin. The material of the second sub-sacrificial structure 42 includes an inorganic material.

If the second sub-sacrificial structure 42 containing the inorganic material is disposed directly on the light-emitting structure 33, the inorganic material is hardly removable except by dry etching. The dry etching is prone to damage the underlying film layer. In these embodiments of the present application, the sacrificial structure 40 is divided into a first sub-sacrificial structure 41 and a second sub-sacrificial structure 42. The second sub-sacrificial structure 42 is an inorganic film layer, and can block moisture ingress from the front. The second sub-sacrificial structure 42 includes a water-soluble resin such as an alcohol-containing resin, and is easily removable, without damaging the underlying film layer during removal.

In some embodiments, the plurality of pixel openings 22 include a first pixel opening 221 and a second pixel opening 222. The step S20 of sequentially forming, at the positions of the corresponding pixel openings 22, the plurality of first carrier structures 32, the plurality of light-emitting structures 33, the plurality of sacrificial structures 40, and the plurality of masking structures 50 includes the following steps.

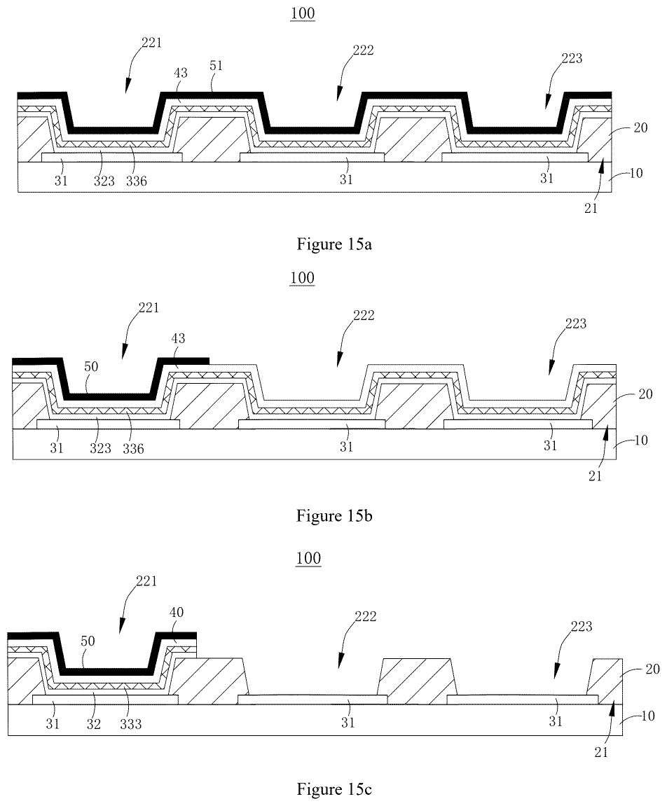

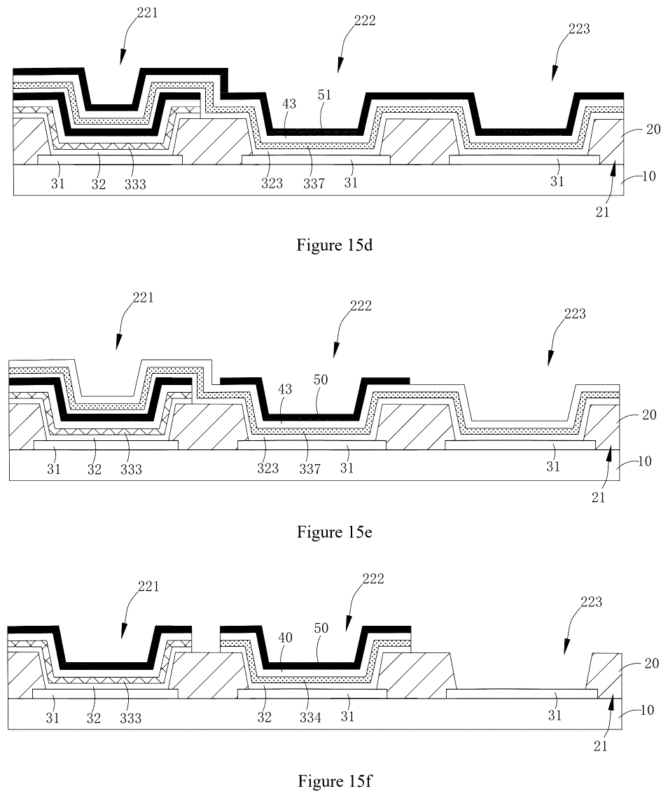

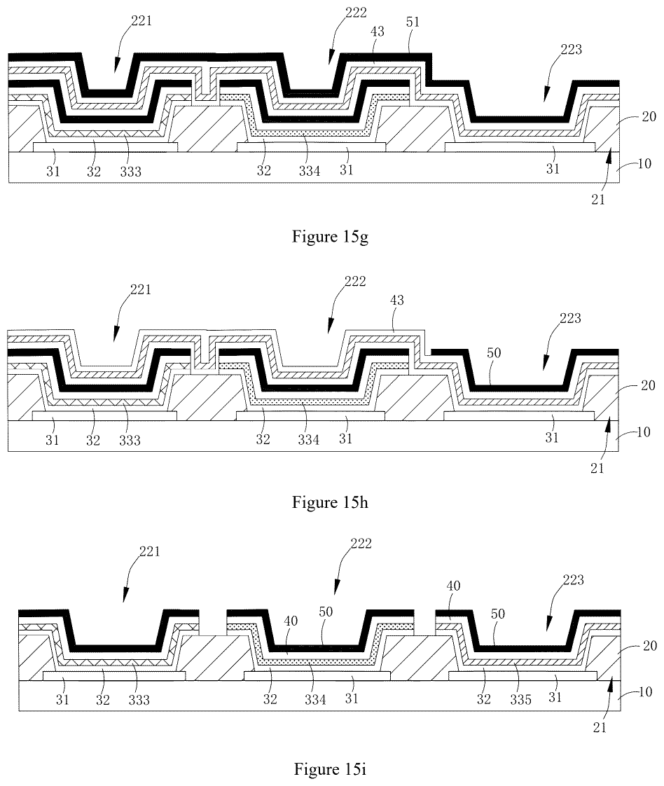

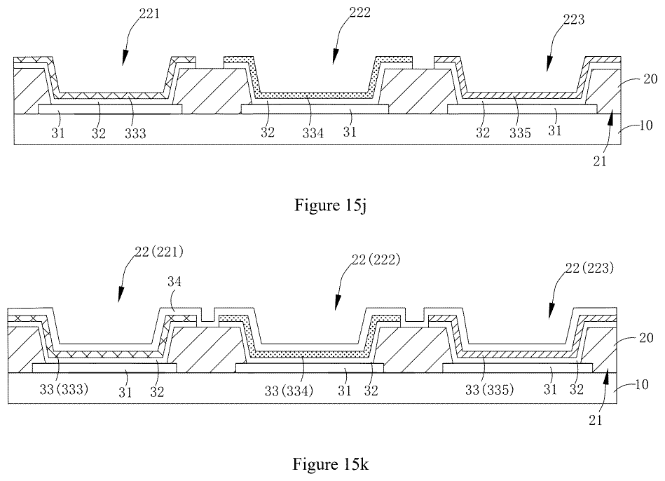

As shown in FIG. 15a, in step S21, a first carrier material layer 323, a first light-emitting material layer 336, and a sacrificial material layer 43 are sequentially formed along a direction away from the substrate 10.

As shown in FIG. 15b, in step S22, a masking structure 50 is formed on one side of the sacrificial material layer 43, the side facing away from the substrate 10. An orthographic projection of the masking structure 50 on the substrate 10 covers an orthographic projection of the first pixel opening 221 on the substrate 10.

A masking material layer may be first prepared on the full surface, as shown in FIG. 15a, and then the masking material layer 51 is treated by an exposure and development process to form a masking structure 50 corresponding to the first pixel opening 221. The width of the masking structure 50 may be set as desired, as long as the masking structure can mask the first pixel opening 221 to protect the light-emitting structure 33 at the position of the first pixel opening 221.

As shown in FIG. 15c, in step S23, by using the masking structure 50 as a mask, the sacrificial material layer 43, the first light-emitting material layer 336, and the first carrier material layer 323 that are located in the second pixel opening 222 and located on one side of the pixel defining portion 21 that faces away from the substrate 10 are removed to obtain a first carrier structure 32, a first light-emitting structure 333, and a sacrificial structure 40 that are located at the position of the first pixel opening 221.

The first carrier structure 32, the first light-emitting structure 333, and the sacrificial structure 40 at the first pixel opening 221 masked by the masking structure 50 are retained, of which one part is located within the first pixel opening 221, and another part is located on one side of the pixel defining portion 21, the side facing away from the substrate 10.

S24: Form a first carrier structure 32, a second light-emitting structure 334, and a sacrificial structure 40 that are located at the position of the second pixel opening 222.

Step S24 may be performed using the same method as steps S21, S22, and S23. As shown in FIG. 15d, a first carrier material layer 323, a second light-emitting material layer 337, and a sacrificial material layer 43 are sequentially formed first.

As shown in FIG. 15e, a masking structure 50 is then formed on one side of the sacrificial material layer 43, the side facing away from the substrate 10. An orthographic projection of the masking structure 50 on the substrate 10 covers an orthographic projection of the second pixel opening 222 on the substrate 10.

As shown in FIG. 15f, subsequently, by using the masking structure 50 as a mask, the sacrificial material layer 43, the second light-emitting material layer 337, and the first carrier material layer 323 that are located in the first pixel opening 221 and the third pixel opening 223 and located on one side of the pixel defining portion 21 that faces away from the substrate 10 are removed to obtain a first carrier structure 32, a second light-emitting structure 334, and a sacrificial structure 40 that are located at the position of the second pixel opening 222.

Likewise, a first carrier structure 32, a third light-emitting structure 335, and a sacrificial structure 40 that are located at the position of the third pixel opening 223 may be further formed.

As shown in FIG. 15g, a first carrier material layer 323, a third light-emitting material layer 338, and a sacrificial material layer 43 are sequentially formed first.

As shown in FIG. 15h, a masking structure 50 is then formed on one side of the sacrificial material layer 43, the side facing away from the substrate 10. An orthographic projection of the masking structure 50 on the substrate 10 covers an orthographic projection of the third pixel opening 223 on the substrate 10.

As shown in FIG. 15i, subsequently, by using the masking structure 50 as a mask, the sacrificial material layer 43, the third light-emitting material layer 338, and the first carrier material layer 323 that are located in the first pixel opening 221 and the second pixel opening 222 and located on one side of the pixel defining portion 21 that faces away from the substrate 10 are removed to obtain a first carrier structure 32, a third light-emitting structure 335, and a sacrificial structure 40 that are located at the position of the third pixel opening 223.

As shown in FIG. 15j, the plurality of masking structures 50 and the plurality of sacrificial structures 40 are sequentially removed.

As shown in FIG. 15k, a second carrier layer 34 that continuously covers the pixel defining portion 21 and the plurality of light-emitting structures 33 is formed.

In some embodiments, the step of sequentially forming the first carrier material layer 323, the first light-emitting material layer 336, and the sacrificial material layer 43 along the direction away from the substrate 10 includes: sequentially forming the first carrier material layer 323, the first light-emitting material layer 336, a first blocking material layer 371, and the sacrificial material layer 43 along the direction away from the substrate 10.

The step of obtaining the first carrier structure 32, the first light-emitting structure 333, and the sacrificial structure 40 that are located at the position of the first pixel opening 221 includes: removing, by using the masking structure 50 as a mask, the sacrificial material layer 43, the first light-emitting material layer 336, the first blocking material layer 371, and the first carrier material layer 323 that are located in the second pixel opening 222 and located on one side of the pixel defining portion 21 that faces away from the substrate 10 to obtain a first carrier structure 32, a first light-emitting structure 333, a first blocking structure 37, and a sacrificial structure 40 that are located at the position of the first pixel opening 221.

In one embodiment, the first blocking structure 37 is a hole blocking structure.

In some embodiments, the step of forming the second carrier layer 34 that continuously covers the pixel defining portion 21 and the plurality of light-emitting structures 33 includes:
sequentially forming a first blocking layer 38 and a first transport layer 342 that continuously cover the pixel defining portion 21, the first light-emitting structure 333, and the second light-emitting structure 334.

In one embodiment, the first blocking layer 38 is a hole blocking layer, and/or the first transport layer 342 is an electron transport layer.

In some embodiments, the first light-emitting material layer 336 includes a first sub-material layer and a second sub-material layer that are sequentially stacked along the direction away from the substrate 10. The step of obtaining the first carrier structure 32, the first light-emitting structure 333, and the sacrificial structure 40 that are located at the position of the first pixel opening 221 includes:
removing, by using the masking structure 50 as a mask, the sacrificial material layer 43, the second sub-material layer, the first sub-material layer, and the first carrier material layer 323 that are located in the second pixel opening 222 and located on one side of the pixel defining portion 21 that faces away from the substrate 10 to obtain a first carrier structure 32, a first light-emitting structure 333, and a sacrificial structure 40 that are located at the position of the first pixel opening 221.

The first light-emitting structure 333 includes a first sub-structure 331 and a second sub-structure 332 that are sequentially stacked along the direction away from the substrate 10. The first sub-structure 331 includes a host material and a dopant material, and the second sub-structure 332 includes the host material.

In one embodiment, the second sub-structure 332 does not include the dopant material.

In one embodiment, the first light-emitting structure 333 is a blue light-emitting structure 33.

In some embodiments, the step of sequentially forming the first carrier material layer 323, the first light-emitting material layer 336, and the sacrificial material layer 43 along the direction away from the substrate 10 includes: sequentially forming the first carrier material layer 323, the first light-emitting material layer 336, a first blocking material layer 371, and the sacrificial material layer 43 along the direction away from the substrate 10.

The step of obtaining the first carrier structure 32, the first light-emitting structure 333, and the sacrificial structure 40 that are located at the position of the first pixel opening 221 includes: removing, by using the masking structure 50 as a mask, the sacrificial material layer 43, the first light-emitting material layer 336, the first blocking material layer 371, and the first carrier material layer 323 that are located in the second pixel opening 222 and located on one side of the pixel defining portion 21 that faces away from the substrate 10 to obtain a first carrier structure 32, a first light-emitting structure 333, a first blocking structure 37, and a sacrificial structure 40 that are located at the position of the first pixel opening 221.

The step of forming the second carrier layer 34 that continuously covers the pixel defining portion 21 and the plurality of light-emitting structures 33 includes: sequentially forming a first blocking layer 38 and a first transport layer 342 that continuously cover the pixel defining portion 21, the first light-emitting structure 333, and the second light-emitting structure 334.

In one embodiment, the first blocking structure 37 is a hole blocking structure, and/or the first blocking layer 38 is a hole blocking layer, and/or the first transport layer 342 is an electron transport layer.

According to a third aspect, the present application further provides a display device. The display device includes the display panel 100 or a display panel 100 prepared by using any one of the preparation methods described above. The display device employs all the above embodiments, and therefore has at least all the beneficial effects brought by the above embodiments, which will not be described in detail herein.

The display device may be any device with a display function, for example, a mobile device, such as a mobile phone, a tablet computer, a laptop computer, a palmtop computer, a vehicle-mounted electronic device, a wearable device, an ultra-mobile personal computer (UMPC), a netbook, or a personal digital assistant (PDA), or a non-mobile device, such as a personal computer (PC), a television (TV), a teller machine, or a self-service machine.

The above descriptions are merely some embodiments of the present application. For convenience and brevity of description, for replacement of other connection manners described above, reference may be made to the corresponding processes in the above method embodiments, and details are not repeated herein. It should be understood that the scope of protection of the present application is not limited thereto, any equivalent modification or replacement that can be easily conceived within the scope disclosed in the present application in the art shall fall within the scope of protection of the present application.

1. A display panel, comprising:
a substrate;
a pixel define layer, disposed on one side of the substrate, wherein the pixel define layer comprises a pixel defining portion and a plurality of pixel openings provided in the pixel defining portion; and
a light-emitting device layer, comprising a plurality of first carrier structures, a plurality of light-emitting structures, and a second carrier layer, wherein the first carrier structures and the light-emitting structures are located at positions of corresponding pixel openings; the light-emitting structures are located on one side of corresponding first carrier structures, the side facing away from the substrate; and the second carrier layer continuously covers the pixel defining portion and the plurality of light-emitting structures.

2. The display panel according to claim 1, wherein the second carrier layer comprises a first transport layer, the light-emitting device layer further comprises a first electrode layer, and the first electrode layer is located on one side of the second carrier layer, the side facing away from the substrate;
orthographic projections of the pixel defining portion and the plurality of light-emitting structures on the substrate are within an orthographic projection of the first electrode layer on the substrate;
the first transport layer is an electron transport layer; and
the first electrode layer is a cathode layer.

3. The display panel according to claim 2, wherein the light-emitting device layer further comprises at least one first blocking structure, and the first blocking structure is located between the second carrier layer and a corresponding light-emitting structure;
the at least one first blocking structure comprises a plurality of first blocking structures one-to-one corresponding to the plurality of light-emitting structures; and the first blocking structure is a hole blocking structure.

4. The display panel according to claim 2, wherein the second carrier layer further comprises a first blocking layer, and the first blocking layer is located between the first transport layer and the plurality of light-emitting structures;
the first blocking layer continuously covers the pixel defining portion and the plurality of light-emitting structures; and
the first blocking layer is a hole blocking layer.

5. The display panel according to claim 2, wherein at least one of the plurality of light-emitting structures comprises a first sub-structure and a second sub-structure, wherein:
the first sub-structure is located on one side of a corresponding first carrier structure, the side facing away from the substrate; and the first sub-structure comprises a host material and a dopant material;
the second sub-structure is located between the first sub-structure and the second carrier layer, the second sub-structure comprises the host material, and the second sub-structure does not comprise the dopant material; and
the plurality of light-emitting structures comprise a blue light-emitting structure, and the blue light-emitting structure comprises the first sub-structure and the second sub-structure.

6. The display panel according to claim 5, wherein the plurality of light-emitting structures further comprise a red light-emitting structure, wherein the red light-emitting structure comprises the first sub-structure and the second sub-structure.

7. The display panel according to claim 5, wherein the plurality of light-emitting structures further comprise a green light-emitting structure, wherein the green light-emitting structure comprises the first sub-structure and the second sub-structure.

8. The display panel according to claim 5, wherein the second carrier layer further comprises a first blocking layer, and the first blocking layer is located between the first transport layer and the plurality of light-emitting structures;
the first blocking layer continuously covers the pixel defining portion and the plurality of light-emitting structures; and
the first blocking layer is a hole blocking layer; and
a thickness of the second sub-structure is D1, which satisfies: 20 nm≤D1≤50 nm.

9. The display panel according to claim 2, wherein the light-emitting device layer further comprises at least one first blocking structure, the first blocking structure is located between the second carrier layer and a corresponding light-emitting structure, the second carrier layer further comprises a first blocking layer, and the first blocking layer continuously covers the pixel defining portion, the plurality of light-emitting structures, and the at least one first blocking structure;
the at least one first blocking structure comprises a plurality of first blocking structures one-to-one corresponding to the plurality of light-emitting structures, and the first blocking layer continuously covers the pixel defining portion and the plurality of first blocking structures;
the first blocking structure is a hole blocking structure; and
the first blocking layer is a hole blocking layer.

10. The display panel according to claim 9, wherein a thickness of the first blocking structure is greater than a thickness of the first blocking layer;
the thickness of the first blocking structure is D2, which satisfies: 23 angstroms≤D2≤40 angstroms; and
the thickness of the first blocking layer is D3, which satisfies: 10 angstroms≤D3≤25 angstroms.

11. The display panel according to claim 2, wherein the light-emitting device layer further comprises a plurality of second electrodes, and each of the second electrodes is located between the substrate and a corresponding first carrier structure and is partially covered by the pixel defining portion;
the second carrier layer further comprises a first injection layer, and the first injection layer is located between the first transport layer and the first electrode layer; and
the first injection layer is an electron injection layer.

12. The display panel according to claim 11, wherein at least one of the plurality of first carrier structures comprises a second blocking structure, the second blocking structure is located between the second carrier layer and a corresponding second electrode, and the second blocking structure is an electron blocking structure;
at least one of the plurality of first carrier structures comprises a second transport structure, the second transport structure is located between the second carrier layer and a corresponding second electrode, and the second transport structure is a hole transport structure; and
at least one of the plurality of first carrier structures comprises a second injection structure, the second injection structure is located between the second carrier layer and a corresponding second electrode, and the second injection structure is a hole injection structure.

13. A preparation method for a display panel, the preparation method comprising:
forming a pixel define layer on one side of a substrate, wherein the pixel define layer comprises a pixel defining portion and a plurality of pixel openings provided in the pixel defining portion;
sequentially forming, at positions of corresponding pixel openings, a plurality of first carrier structures, a plurality of light-emitting structures, a plurality of sacrificial structures, and a plurality of masking structures;
sequentially removing the plurality of masking structures and the plurality of sacrificial structures; and
forming a second carrier layer that continuously covers the pixel defining portion and the plurality of light-emitting structures.

14. The preparation method according to claim 13, wherein the second carrier layer comprises a first transport layer, and after the step of forming the second carrier layer that continuously covers the pixel defining portion and the plurality of light-emitting structures, the method further comprises:
forming a first electrode layer on one side of the second carrier layer, the side facing away from the substrate,
wherein the first transport layer is an electron transport layer, the first electrode layer is a cathode layer, each of the sacrificial structures comprises a first sub-sacrificial structure and a second sub-sacrificial structure disposed sequentially along a direction away from the substrate, a material of the first sub-sacrificial structure comprises a water-soluble resin, and a material of the second sub-sacrificial structure comprises an inorganic material.

15. The preparation method according to claim 13, wherein the plurality of pixel openings comprise a first pixel opening and a second pixel opening, and the step of sequentially forming, at the positions of the corresponding pixel openings, the plurality of first carrier structures, the plurality of light-emitting structures, the plurality of sacrificial structures, and the plurality of masking structures comprises:
sequentially forming a first carrier material layer, a first light-emitting material layer, and a sacrificial material layer along a direction away from the substrate;
forming a masking structure on one side of the sacrificial material layer, the side facing away from the substrate, wherein an orthographic projection of the masking structure on the substrate covers an orthographic projection of the first pixel opening on the substrate;
removing, by using the masking structure as a mask, the sacrificial material layer, the first light-emitting material layer, and the first carrier material layer that are located in the second pixel opening and located on one side of the pixel defining portion that faces away from the substrate to obtain a first carrier structure, a first light-emitting structure, and a sacrificial structure that are located at a position of the first pixel opening; and
forming a first carrier structure, a second light-emitting structure, and a sacrificial structure that are located at a position of the second pixel opening.

16. The preparation method according to claim 15, wherein
the step of sequentially forming the first carrier material layer, the first light-emitting material layer, and the sacrificial material layer along the direction away from the substrate comprises: sequentially forming the first carrier material layer, the first light-emitting material layer, a first blocking material layer, and the sacrificial material layer along the direction away from the substrate; and
the step of obtaining the first carrier structure, the first light-emitting structure, and the sacrificial structure that are located at the position of the first pixel opening comprises: removing, by using the masking structure as a mask, the sacrificial material layer, the first light-emitting material layer, the first blocking material layer, and the first carrier material layer that are located in the second pixel opening and located on one side of the pixel defining portion that faces away from the substrate to obtain a first carrier structure, a first light-emitting structure, a first blocking structure, and a sacrificial structure that are located at the position of the first pixel opening, wherein the first blocking structure is a hole blocking structure.

17. The preparation method according to claim 15, wherein the step of forming the second carrier layer that continuously covers the pixel defining portion and the plurality of light-emitting structures comprises:
sequentially forming a first blocking layer and a first transport layer that continuously cover the pixel defining portion, the first light-emitting structure, and the second light-emitting structure,
wherein the first blocking layer is a hole blocking layer, and the first transport layer is an electron transport layer.

18. The preparation method according to claim 17, wherein the first light-emitting material layer comprises a first sub-material layer and a second sub-material layer that are sequentially stacked along the direction away from the substrate, and the step of obtaining the first carrier structure, the first light-emitting structure, and the sacrificial structure that are located at the position of the first pixel opening comprises:
removing, by using the masking structure as a mask, the sacrificial material layer, the second sub-material layer, the first sub-material layer, and the first carrier material layer that are located in the second pixel opening and located on one side of the pixel defining portion that faces away from the substrate to obtain a first carrier structure, a first light-emitting structure, and a sacrificial structure that are located at the position of the first pixel opening,
wherein the first light-emitting structure comprises a first sub-structure and a second sub-structure that are sequentially stacked along the direction away from the substrate, the first sub-structure comprises a host material and a dopant material, the second sub-structure comprises the host material, the second sub-structure does not comprise the dopant material, and the first light-emitting structure is a blue light-emitting structure.

19. The preparation method according to claim 15, wherein
the step of sequentially forming the first carrier material layer, the first light-emitting material layer, and the sacrificial material layer along the direction away from the substrate comprises: sequentially forming the first carrier material layer, the first light-emitting material layer, a first blocking material layer, and the sacrificial material layer along the direction away from the substrate; and
the step of obtaining the first carrier structure, the first light-emitting structure, and the sacrificial structure that are located at the position of the first pixel opening comprises: removing, by using the masking structure as a mask, the sacrificial material layer, the first light-emitting material layer, the first blocking material layer, and the first carrier material layer that are located in the second pixel opening and located on one side of the pixel defining portion that faces away from the substrate to obtain a first carrier structure, a first light-emitting structure, a first blocking structure, and a sacrificial structure that are located at the position of the first pixel opening, wherein the first blocking structure is a hole blocking structure; and
the step of forming the second carrier layer that continuously covers the pixel defining portion and the plurality of light-emitting structures comprises: sequentially forming a first blocking layer and a first transport layer that continuously cover the pixel defining portion, the first light-emitting structure, and the second light-emitting structure, wherein the first blocking layer is a hole blocking layer, and the first transport layer is an electron transport layer.

20. A display device, comprising:
a display panel, comprising:
a substrate;
a pixel define layer, disposed on one side of the substrate, wherein the pixel define layer comprises a pixel defining portion and a plurality of pixel openings provided in the pixel defining portion; and
a light-emitting device layer, comprising a plurality of first carrier structures, a plurality of light-emitting structures, and a second carrier layer, wherein the first carrier structures and the light-emitting structures are located at positions of corresponding pixel openings; the light-emitting structures are located on one side of corresponding first carrier structures, the side facing away from the substrate; and the second carrier layer continuously covers the pixel defining portion and the plurality of light-emitting structures.
